(19) United States
(12) Patent Application Publication
(10) Pub. No.: US 2008/0054420 A1
(43) Pub. Date: Mar. 6, 2008

(54) SEMICONDUCTOR PACKAGE STRUCTURE AND METHOD OF MANUFACTURE

(75) Inventors: Guan Keng Quah, Gilbert, AZ (US); Hou Boon Tan, Seremban (MY); Qiang Hua Pan, Leshan (CN)

Correspondence Address: BRADLEY J. BOTSCH;SEMICONDUCTOR COMPONENTS INDUSTRIES, LLC, 5005 E. MCDOWELL ROAD, P.O.BOX 62890, INTELLECTUAL PROPERTY DEPT. - A700, PHOENIX, AZ, 85082, US

(73) Assignee: Semiconductor Components Industries, LLC.

(21) Appl. No.: 11/466,539

(22) Filed: Aug. 23, 2006

(51) Int. Cl. H01L 23/495

(52) U.S. Cl. 257/676

(57) ABSTRACT

In one embodiment, a semiconductor package includes a lead frame having a lead portion and pad portion that are offset with respect to each other. The lead portion includes a deep formed impression. An up-bent portion connects the lead portion to the pad portion.

### FIELD OF THE INVENTION

This invention relates generally to electronic devices, and more specifically to semiconductor packages and methods of assembly.

### BACKGROUND OF THE INVENTION

The handheld consumer products market is aggressive in the miniaturization of portable electronics. Driven primarily by the cellular phone, MP3, and digital camera markets, manufacturers of these devices are challenged by ever shrinking formats. This challenge asserts pressure on semiconductor component manufacturers to design their products to command the smallest area and thinnest height possible.

In certain semiconductor package designs, some portions of the lead frame are offset with respect to other portions. For example, a die bond flag portion may be offset from lead portions of the lead frame. Physical bending of the lead frame structure is one known technique used to provide such offset structures. One problem with this approach is that as lead frame materials are reduced in thickness to meet minimum package height requirements, the bending process produces significant weaknesses in the bend or neck portions of the lead frame. These portions often become weaker during the assembly process, or in extreme cases, break off altogether. This directly impacts the reliability of the final component as well as manufacturing costs and cycle time.

Masked etching techniques or selective etch techniques also are used to thin sections of lead frames to form required offset or inset portions. However, because the demand for thinner packages requires a thinner starting lead frame to begin with, the additional etching step used to form the offset or inset structures results in portions that are too thin and weak to support components such as the semiconductor die and the connecting structures. This also impacts the reliability of the final component as well as manufacturing costs and cycle time.

Accordingly, a need exists for a package structure and method of assembly that provide for thinner, more reliable and cost effective packages.

### BRIEF DESCRIPTION OF THE DRAWINGS

FIG. 1 illustrates a cross-sectional view of a first embodiment of a package structure;

FIG. 2 illustrates a cross-sectional view of a second embodiment of a package structure;

FIG. 3 illustrates a cross-sectional view of a third embodiment of a package structure;

FIGS. 4 and 5 illustrate partial cross-sectional views of a support structure during fabrication;

FIG. 6 illustrates a partial cross-sectional view of a support structure during an alternative step in fabrication; and

FIG. 7 illustrates a process flow for fabricating a package structure.

For ease of understanding, elements in the drawing figures are not necessarily drawn to scale, and like element numbers are used where appropriate throughout the various figures to denote the same or similar elements. Additionally, descriptions and details of well-known steps and elements are omitted for simplicity of the description. Although the package structure is explained herein as various SOD-923 embodiments, a person of ordinary skill in the art will appreciate that other package structures are possible in accordance with the present invention.

### DETAILED DESCRIPTION OF THE DRAWINGS

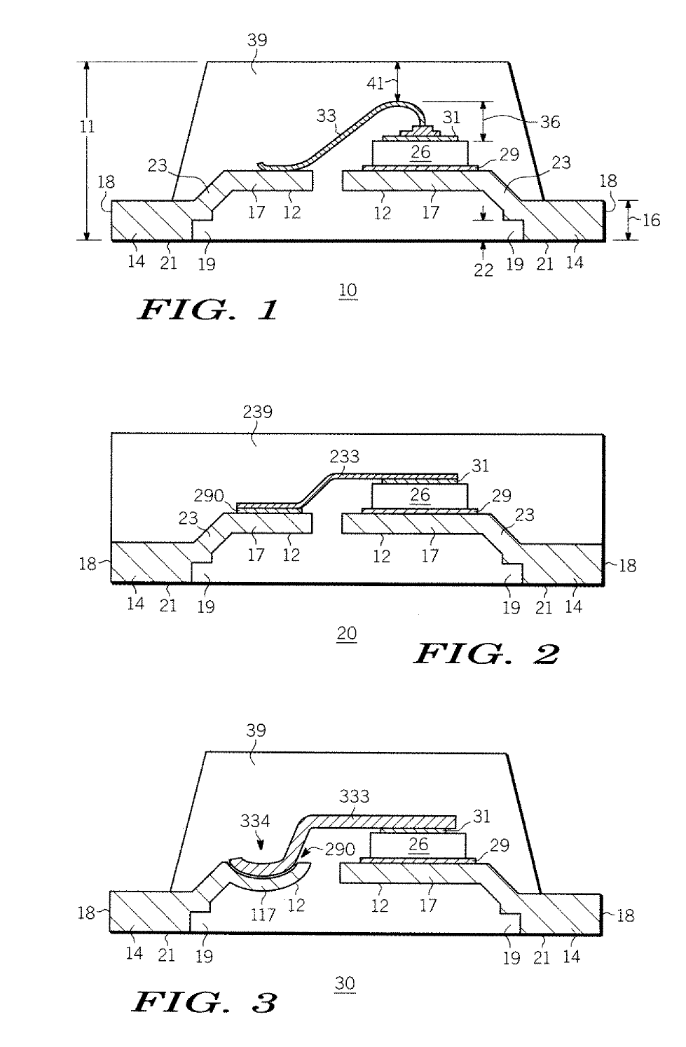

FIG. 1 shows a cross-sectional view of a package structure 10 in accordance with a first embodiment. Package structure 10 is shown as a SOD-923 package having a thin profile or reduced height 11 resulting specifically from features of lead frame structure 12. In one embodiment, height 11 is less than about 0.4 mm.

Lead frame or support structure 12 is shown with leads or lead portions 14, and pads, pad portions, or bonding portions 17. In one embodiment, lead frame 12 has a thickness 16 of about 0.10 mm to about 0.12 mm. One or more of leads 14 include a formed, coined or deep coined step, feature, mark, imprint or impression 19 formed in one or more surfaces. In the embodiment shown, coined impressions 19 are formed in proximity to or adjacent to exposed or bonding surfaces 21 of leads 14. As used herein, the term “coined” refers to a process where lead frame 12 is placed between or contained within a closed set of dies having a predetermined shape, and lead frame 12 is cold worked or physically squeezed under pressure to form features 19 in accordance with the predetermined shape of the dies. In one embodiment, coined impressions 19 are formed to a depth 22 on the order of about 0.025 mm. Although impressions 19 are shown in FIG. 1 with sharp corners and straight edges, it is understood that impressions 19 may include, for example, tapered edges and rounded inside corners, or the like. In an alternative embodiment, formed impressions 19 are formed using masked etching techniques either singularly or in combination with coining techniques.

Lead frame 12 further includes up-bent, neck or connective portions 23 that extend between or connect leads 14 and pad portions 17. In this embodiment, impressions 19 are formed on a first major surface of leads 14, and neck portions 23 are on a second major surface of leads 14 opposite the first major surface. Also, pad portions 17 are offset with respect to leads 14 (i.e., pad portions 17 are in a different horizontal plane with respect to leads 14). Up-bent portions 23 are formed after impressions 19 are formed in lead frame 12 using conventional bending techniques. This process sequence results in up-bent portions 23 having increased strength compared to prior art structures using thin lead frames with bend techniques only, or using etch techniques to form offset portions. That is, the combination of forming impressions 19 and forming up-bent portions 23 provides a thin yet strong lead frame 12 that allows for a thinner package.

By way of example, lead frame 12 comprises a conductive material such as copper, a copper alloy, aluminum, or an iron/nickel. In another embodiment, lead frame 12 is plated with an additional material(s) such as copper, silver, nickel-palladium, gold or the like.

Package structure 10 also includes an electronic component or semiconductor device 26 coupled or attached to one of pads 17. By way of example, device 26 comprises a power MOSFET device, a bipolar transistor, an insulated gate bipolar transistor, a thyristor, a diode, an analog or digital integrated circuit, a sensor, a passive component, combinations thereof, or another electronic device. One side of device 26 is attached to pad 17 using a conventional solder die attach or epoxy die attach layer 29. Device 26 further includes a metallization or contact layer 31 formed on another surface. Contact layer 31 comprises, for example, aluminum, aluminum/silicon, titanium/nickel/silver, titanium/nickel/gold, chromium/nickel/gold, or the like.

A conductive connective structure or wire bond 33 is attached to contact layer 32 and further attached to another pad 17 as shown in FIG. 1. By way of example, wire bond 33 has a loop height 36 on the order of about 0.10 mm, and is formed using conventional wire bonding techniques.

Package structure 10 further includes a molded encapsulating layer or protective layer 39, which covers device 26, wire bond 33, and at least portions of lead frame 12. By way of example, encapsulating layer 39 comprises an epoxy resin. In the embodiment shown, encapsulating layer 39 is set back or inset from end surfaces 18 of leads 14 leaving multiple surfaces of leads 14 exposed. In one embodiment, encapsulating layer 39 extends above wire bond 33 a distance 41 on the order of about 0.04 mm. This distance provides sufficient protection of the encapsulated components of even if laser marking is used to identify package 10. In this embodiment, a portion of encapsulating layer 39 extends between leads 14 and further covers or passivates impressions 19. Impressions 19 provide or define sharp and consistent bonding surfaces 21, which provide for better alignment and bonding when package 10 is attached to a next level of assembly.

FIG. 2 shows a cross-sectional view of a package structure 20 in accordance with a second embodiment. Structure 20 is similar to structure 10 except that structure 20 incorporates a different conductive connective structure 233. In this embodiment, conductive connective structure 233 comprises a conductive clip or a conductive ribbon bond. Conductive connective structure 233 is attached to pad 17 using an attach layer 290, which comprises a solder or epoxy attach layer. In addition, structure 20 includes an encapsulating layer 239 that extends out to or in proximity to ends 18 of leads 14. In one embodiment, structure 20 is formed using a MAP over-molding process, and individual structures 20 are formed by singulating through encapsulating layer 239 and leads 14.

FIG. 3 shows a cross-sectional view of a package structure 30 in accordance with a third embodiment. Structure 30 is similar to structures 10 and 20 except that structure 30 incorporates a conductive connective structure 333 having an end 334 that includes a means for alignment to pad 117 of lead frame 12. In the embodiment shown, the means for alignment or alignment structure includes a concave cup like shape that mates or aligns to pad 117, which also is shaped similarly. Alternatively, end 334 comprises a flat shape having one or more positioning bodies, tines, or projections extending therefrom that mate with or assist in aligning end 334 with pads 17 or 117.

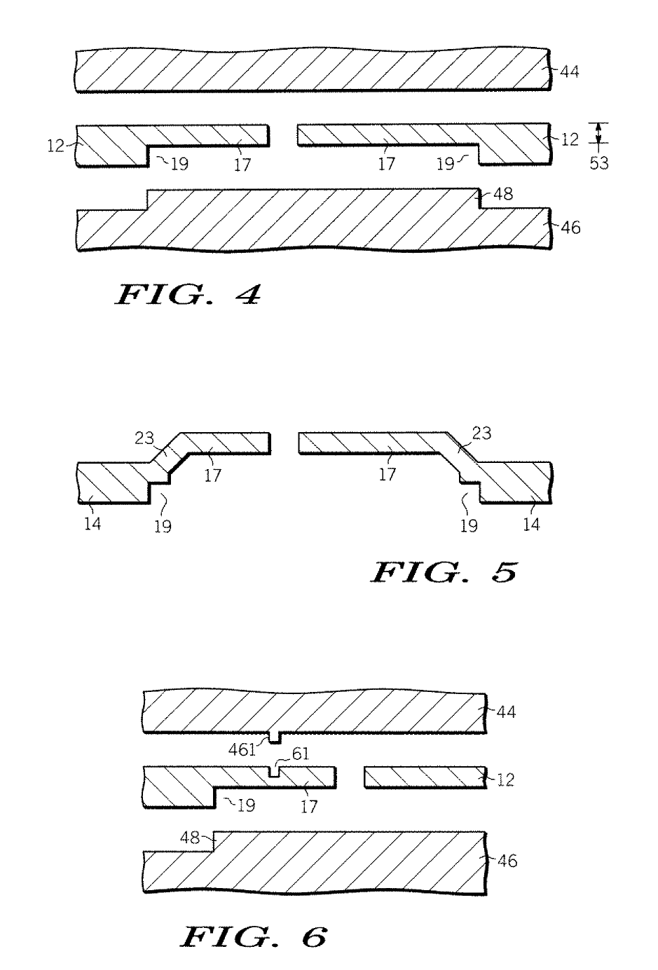

FIG. 4 shows a partial cross-sectional view of lead frame 12 at an early step in fabrication. Lead frame 12 is shown enclosed between first die plate 44 and a second die plate 46, which are used to deep coin impressions or marks 19. Second die plate 46 includes a punch or raised portion 48 that provides the desired shape for coined impression 19. Impressions 19 are conveniently deep coined when lead frame 12 is further stamped to form other features or to remove unwanted material. In one embodiment, pads 17 have a thickness 53 of about 0.075 mm after coining, which provides a stable platform for further assembly. After impressions 19 are coined in lead frame 112, lead frame 12 is optionally plated with a selected material such as copper, silver, or the like.

FIG. 5 shows a partial cross-sectional view of lead frame 12 after a subsequent step in fabrication. During this subsequent step, portions of lead frame 12 are up bent to a desired height to form neck portions 23, and to provide the desired position of pads 17.

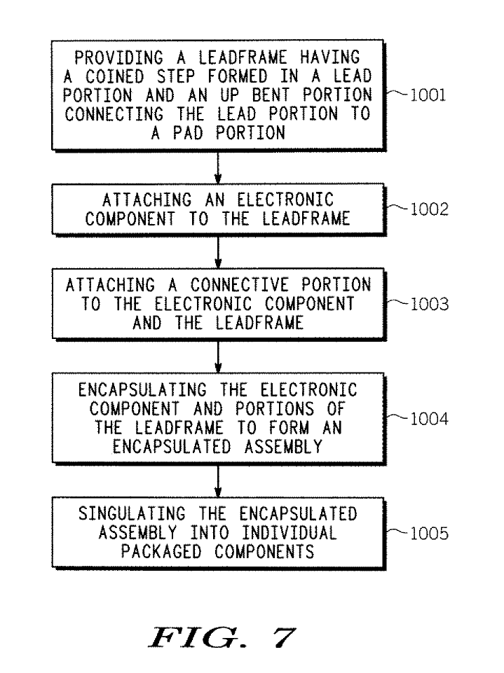

FIG. 6 shows a partial cross-sectional view of lead frame 12 at an early step of fabrication in accordance with alternative embodiment. Lead frame 12 is shown enclosed between first die plate 44 and second die plate 46 as described in conjunction with FIG. 4. In this embodiment, first die plate 44 further includes a protrusion 461, which is used to provide a coined alignment impression or structure 61 in pad 17. Coined alignment structure 61 is another example of an alignment means or structure as previously described in package 30 of FIG. 3. Coined alignment structure 61 may have various shapes to mate with a corresponding shape of end 334 of conductive connective structure 333 or a portion thereof.

FIG. 7 shows a general process flow for forming a package structure using lead frame 12 having formed impressions 19 and neck portions 23. In step 1001, lead frame 12 is provided after the steps described in FIGS. 4 and 5 have been performed either by the manufacturer of the package component, or by a supplier lead frame piece parts.

In step 1002, electronic components 26 are attached to desired pads 17 of lead frame 12 using a solder attach or epoxy attach layer. In step 1003, conductive connective portions 33, 233, and/or 333 are attached to electronic components 26 and pads 17 and/or 117 to form a sub-assembly. In step 1004, the sub-assembly is then placed in a molding apparatus to form encapsulating layers 39 over portions of the sub-assembly, or to form encapsulating layer 339 over all of the sub-assembly. This step forms an encapsulated assembly. In step 1005, the encapsulated assembly is singulated or separated into individual packaged components 10, 20, and/or 30.

In summary, a package structure includes a lead frame having a lead portion and pad portion that are offset. The lead portion includes a deep formed impression. An up-bent portion connects the lead portion to the pad portion. The combination of the deep formed feature and the up-bent portion provides a thin but strong lead frame structure to allow for thinner package structures where offset portions are required.

Although the invention has been described and illustrated with reference to specific embodiments thereof, it is not intended that the invention be limited to these illustrative embodiments.

What is claimed is:

1. A semiconductor package comprising:
a lead frame structure including a first lead portion, a first pad portion, and a first neck portion connecting the first lead portion to the first pad portion, wherein the first lead portion has a coined feature formed in one major surface;
an electronic component coupled to the pad portion; and
an encapsulating layer formed overlying the electronic component and at least a portion of the lead frame structure.

2. The structure of claim 1 further comprising a second lead portion having another coined feature formed in one major surface, wherein the electronic component is coupled to the second lead portion with a conductive connective structure.

3. The structure of claim 2, wherein the conductive connective structure comprises a wire bond.

4. The structure of claim 2, wherein the conductive connective structure comprises a conductive clip.

5. The structure of 4, wherein the conductive clip or the second lead portion includes an alignment structure.

6. The structure of claim 2, wherein the conductive connective structure comprises a ribbon bond.

7. The structure of claim 2, further comprising a second pad portion offset from the second lead portion and coupled thereto with a second neck portion.

8. The structure of claim 1 wherein the coined feature comprises a step shape having a depth of about 0.025 millimeter.

9. The structure of claim 1, wherein the coined feature is formed on a first major surface of the first lead portion, and wherein the first neck portion is in proximity to a second major surface of the first lead portion opposite the first major surface.

10. The structure of claim 1, wherein the semiconductor package structure comprises a SOD-923 configuration.

11. A package structure comprising:
a first lead portion having a major surface and a first impression formed in proximity to the major surface of the first lead portion;
a second lead portion having a major surface and a second impression formed in proximity to the major surface of the second lead portion;
a first pad portion offset from the first lead portion, wherein a first neck portion connects the first lead portion to the first pad portion;
a second pad portion offset from the second lead portion, wherein a second neck portion connects the second lead portion to the second pad portion;
an electronic component coupled to the first pad portion;
a conductive connective structure coupled to the electronic component and the second pad portion; and
an encapsulating layer covering the electronic component, the conductive connective structure, and portions of the first and second lead portions.

12. The structure of claim 11, wherein the first and second impressions comprise coined impressions, and wherein the encapsulating layer covers the first and second coined impressions.

13. The structure of claim 11, wherein the second pad portion includes a coined alignment impression configured to assist in aligning the conductive connective structure with the second pad portion.

14. The structure of claim 11, wherein the structure has a height less than about 0.4 millimeters.

15. The structure of claim 11, wherein the structure is configured as a SOD-923 package.

16. A method for forming a semiconductor packaged structure comprising the steps of:
providing a lead frame structure including a first lead portion, a first pad portion, and a neck portion connecting the first lead portion to the first pad portion, wherein the first lead portion has a coined feature formed in one major surface;
attaching an electronic component to the lead frame;
attaching a conductive connective portion to the electronic component and the lead frame; and
encapsulating the electronic component and portions of the lead frame.

17. The method of claim 16, wherein the step of providing the lead frame structure includes providing the lead frame structure further comprising a second lead portion having a coined feature formed in one major surface, and wherein the step of attaching the conductive connective portion includes attaching the conductive connective portion to the electronic component and the second lead portion.

18. The method of claim 17, wherein the step of attaching the conductive connective portion comprises attaching a wire bond.

19. The method of claim 17, wherein the step of attaching the conductive connective portion comprises attaching a conductive clip.

20. The method of 19, wherein the step of a attaching the conductive clip includes attaching a conductive clip having a means for aligning the conductive clip to the second lead portion.

21. The method of claim 17, wherein the step of attaching the conductive connective portion comprises attaching a ribbon bond.
